(19) United States
(12) Patent Application Publication
(10) Pub. No.: US 2009/0061651 A1
(43) Pub. Date: Mar. 5, 2009

(54) Substrate processing apparatus and method for manufacturing semiconductor device

(75) Inventors: Sadao Nakashima, Toyama-shi (JP); Takahiro Maeda, Toyama-shi (JP); Jie Wang, Toyama-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., TOKYO (JP)

(21) Appl. No.: 12/230,679

(22) Filed: Sep. 3, 2008

(30) Foreign Application Priority Data
Sep. 5, 2007 (JP) 2007-230522

(51) Int. Cl. C23C 16/34; H01L 21/31

(52) U.S. Cl. 438/791; 118/728; 257/E21.24

(57) ABSTRACT

A substrate processing apparatus comprising: a reaction tube that processes a substrate; a support portion that supports the substrate in the reaction tube; a process gas supply line that supplies a process gas into the reaction tube; and an exhaust line that exhausts an inside of the reaction tube, wherein the process gas is supplied into the reaction tube to form a silicon nitride film on the substrate, at least the reaction tube is made of quartz, a plurality of projections are provided on the inner wall of the reaction tube, and the diameter of the projections is larger than 2 μm but smaller than 86 μm.

### BACKGROUND OF THE INVENTION

1. Field of the Invention

The present invention relates to a substrate processing apparatus that processes a substrate, such as a semiconductor wafer and a glass substrate, and a method for manufacturing a semiconductor device.

2. Description of the Related Art

When a substrate processing apparatus of this type is used to form an SiN (silicon nitride) film on a wafer, for example, using CVD (Chemical Vapor Deposition), the SiN film is grown (deposited) also on the surface of a quartz member, such as a reaction tube and a support portion. When the thickness of the SiN film becomes greater than a predetermined value (a critical film thickness), the SiN film peels off the surface of the quartz member, resulting in particles that attach to the wafer. It is known that such an SiN film, when grown to a thickness of approximately 1 μm, begins to peel off the surface of the quartz member. It is believed that the peeling of the SiN film results from the difference in coefficient of expansion between the quartz member and the SiN film (difference in expansion between the quartz member and the SiN film due to the maximum difference between the temperature at which the film is formed and the temperature at which the apparatus is held in a period other than the film formation), but the peeling does not greatly depend on the film forming conditions other than the temperature.

To prevent such particles from attaching to the wafer, a technique is known in which a thin film deposited in a reaction furnace, for example, by repeating a film formation step is removed to clean the reaction furnace (JP-A-2004-288903, for example). A method is also known in which an SiN film that has grown on, for example, the surface of a quartz member is removed by using a reactive gas whenever the thickness of the SiN film becomes approximately 1 μm, or by removing the quartz member and cleaning the SiN film using a cleaning fluid.

In the techniques of the related art described above, however, the film formation process needs to be temporarily terminated to remove the SiN film, disadvantageously resulting in a reduced operating rate of the apparatus.

### SUMMARY OF THE INVENTION

An object of the invention is to solve the above problem and provide a substrate processing apparatus with the operating rate thereof improved and a method for manufacturing a semiconductor device.

A first aspect of the invention is a substrate processing apparatus comprising a reaction tube that processes a substrate; a support portion that supports the substrate in the reaction tube; a process gas supply line that supplies a process gas into the reaction tube; and an exhaust line that exhausts an inside of the reaction tube, wherein the process gas is supplied into the reaction tube to form a silicon nitride film on the substrate, at least the reaction tube is made of quartz, a plurality of projections are provided on the inner wall of the reaction tube, and the diameter of the projections is larger than 2 μm but smaller than 86 μm.

It is preferable that the diameter of the projections is larger than 2 μm but smaller than 64 μm.

It is preferable that the diameter of the projections is larger than or equal to 20 μm but smaller than or equal to 42 μm.

It is preferable that the length of the gap between adjacent pairs of the projections is smaller than 100 μm.

It is preferable that the length of the gap between adjacent pairs of the projections is smaller than or equal to 50 μm.

It is preferable that the support portion is made of quartz, a plurality of projections are provided on the surface of the support portion, and the diameter of the projections is larger than 2 μm but smaller than 86 μm.

It is preferable that the reaction tube includes an inner tube and an outer tube provided outside the inner tube, a plurality of projections are provided on the inner walls of the inner and outer tubes, and the diameter of the projections is larger than 2 μm but smaller than 86 μm.

A second aspect of the invention is a substrate processing apparatus comprising a reaction tube that processes a substrate; a support portion that supports the substrate in the reaction tube; a process gas supply line that supplies a process gas into the reaction tube; and an exhaust line that exhausts an inside of the reaction tube, wherein the process gas is supplied into the reaction tube to form a silicon nitride film on the substrate, at least the reaction tube is made of quartz, a plurality of projections are provided on the inner wall of the reaction tube, and the length of the gap between adjacent pairs of the projections is smaller than 100 μm.

A third aspect of the invention is a substrate processing apparatus comprising a reaction tube that processes a substrate; a support portion that supports the substrate in the reaction tube; a silane-based gas supply line that supplies a silane-based gas into the reaction tube; an ammonia gas supply line that supplies ammonia gas into the reaction tube; and an exhaust line that exhausts an inside of the reaction tube, wherein the silane-based gas and ammonia gas are supplied into the reaction tube to form a silicon nitride film on the substrate, at least the reaction tube is made of quartz, a plurality of projections are provided on the inner wall of the reaction tube, the diameter of the projections is larger than or equal to 20 μm but smaller than or equal to 42 μm, and the length of the gap between adjacent pairs of the projections is smaller than or equal to 50 μm.

A fourth aspect of the invention is a method for manufacturing a semiconductor device, comprising the steps of loading a substrate into a reaction tube made of quartz with a plurality of projections provided on the inner wall of the reaction tube, the diameter of the projections being larger than 2 μm but smaller than 86 μm, supplying a process gas into the reaction tube to form a silicon nitride film on the substrate; and unloading the substrate on which the silicon nitride film has been formed from the reaction tube.

A fifth aspect of the invention is a method for manufacturing a semiconductor device, comprising the steps of loading a substrate into a reaction tube made of quartz with a plurality of projections provided on the inner wall of the reaction tube, supplying a process gas into the reaction tube to form a silicon nitride film on the substrate; and unloading the substrate on which the silicon nitride film has been formed from the reaction tube, wherein when the film thickness at which cracking or peeling is initiated in the silicon nitride film deposited on the inner wall of the reaction tube is set to a value larger than t μm, the length of the gap between adjacent pairs of the projections is set to a value smaller than 100 μm/t.

According to the invention, since a plurality of projections having a predetermined diameter are provided on the surface of a quartz member, the film thickness at which cracking or peeling is initiated in an SiN film deposited on the quartz member can be a large value. It is thus possible to reduce the frequency of removing and cleaning the SiN film, and hence improve the operating rate of the apparatus.

### BRIEF DESCRIPTION OF THE DRAWINGS

FIG. 1 is a cross-sectional view showing a substrate processing apparatus according to an embodiment of the invention;

FIGS. 2A and 2B show an inner tube used in the substrate processing apparatus according to the embodiment of the invention: FIG. 2A is a longitudinal cross-sectional view and FIG. 2B is a partially enlarged view of FIG. 2A;

FIGS. 3A and 3B are partially enlarged views of the inner tube of the embodiment on which an SiN film is deposited: FIG. 3A is a plan view and FIG. 3B is a cross-sectional view taken along the line A-A in FIG. 3A;

FIG. 4 is a table showing experimental results in an example of the invention;

FIGS. 5A and 5B explain a mechanism of cracking in an SiN film deposited on the surface of a quartz member: FIG. 5A shows a model in which a quartz member has a flat surface and FIG. 5B shows a model in which a quartz member has a plurality of hemispherical projections provided thereon;

FIGS. 6A and 6B explain how to form projections using flame spraying: FIG. 6A shows quartz particles being sprayed onto a quartz member and FIG. 6B shows a sprayed quartz member;

FIGS. 7A and 7B explain the structure of a quartz member in other embodiments: FIG. 7A explains a recessed structure and FIG. 7B explains a structure having projections and recesses;

FIGS. 8A and 8B show an inner tube in a comparative example: FIG. 8A is a longitudinal cross-sectional view and FIG. 8B is a partially enlarged view of FIG. 8A; and

FIGS. 9A and 9B are partially enlarged views of the inner tube of the comparative example on which an SiN film is deposited: FIG. 9A is a plan view and FIG. 9B is a cross-sectional view taken along the line B-B in FIG. 9A.

### DESCRIPTION OF THE PREFERRED EMBODIMENT

An embodiment of the invention will be described below with reference to the drawings.

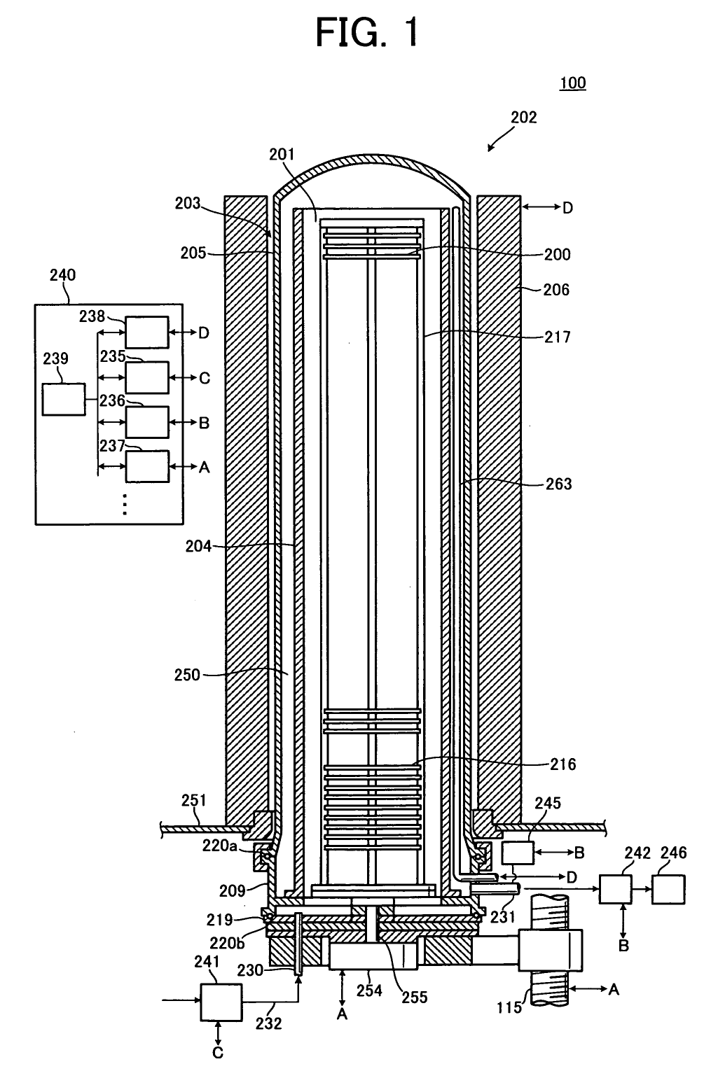

FIG. 1 is a schematic configuration diagram of a processing furnace 202 in a substrate processing apparatus 100 preferably used in the embodiment of the invention. FIG. 1 is shown as a cross-sectional view taken along a line.

As shown in FIG. 1, the processing furnace 202 includes a heater 206 as a heating mechanism. The heater 206 has a cylindrical shape and is vertically supported by and fixed to a heater base 251 as a retainer plate.

A process tube 203 as a reaction tube is disposed inside the heater 206 concentrically with the heater 206. The process tube 203 includes an inner tube 204 as an inner reaction tube and an outer tube 205 as an outer reaction tube provided outside the inner tube 204. The inner tube 204 is made of a heat-resistant material, such as quartz (SiO₂), and has a cylindrical shape with open upper and lower ends. A processing chamber 201 is formed in the hollow portion of the inner tube 204, and a boat 217, which will be described later, can accommodate vertically aligned wafers 200, each of which is a substrate, horizontally placed at multiple levels. The outer tube 205 is made of a heat-resistant material, such as quartz, and has a cylindrical shape with a closed upper end and an open lower end, the inner diameter of the outer tube 205 being larger than the outer diameter of the inner tube 204. The outer tube 205 is disposed concentrically with the inner tube 204.

A manifold 209 is disposed below the outer tube 205 concentrically therewith. The manifold 209 is made of, for example, stainless steel, and has a cylindrical shape with open upper and lower ends. The manifold 209 engages the inner tube 204 and the outer tube 205 and supports the two tubes. An O ring 220a is provided as a sealing member between the manifold 209 and the outer tube 205. The manifold 209 is supported by the heater base 251, and hence the process tube 203 is vertically fixed. The process tube 203 and the manifold 209 form a reaction chamber.

A nozzle 230 as a gas introduction portion is connected to a seal cap 219, which will be described later, in such a way that the nozzle 230 communicates with the processing chamber 201. The nozzle 230 is connected to a gas supply tube 232 as a process gas supply line that supplies a process gas. A process gas supply source and an inert gas supply source (not shown), the process gas being a silane-based gas, ammonia gas and other gases, are connected to the upstream portion of the gas supply tube 232, which is on the opposite side to the portion where the gas supply tube 232 is connected to the nozzle 230, and an MFC (mass flow controller) 241 as a gas flow control device is disposed part way along the gas supply tube 232. The gas supply tube 232 is used as a silane-based gas supply line or an ammonia gas supply line when a silane-based gas or ammonia gas is supplied into the process tube 203. A gas flow control unit (gas flow controller) 235 is electrically connected to the MFC 241, and the gas flow control unit 235 and the MFC 241 are configured to control the flow rate of the supplied gas at a desired timing so that the flow rate becomes a desired value.

The manifold 209 is provided with an exhaust tube 231 as an exhaust line that exhausts the atmosphere in the processing chamber 201. The exhaust tube 231 is disposed at the lower end of a tubular space 250, which is the gap between the inner tube 204 and the outer tube 205, and communicates with the tubular space 250. An evacuation device 246, such as a vacuum pump, is connected to the downstream portion of the exhaust tube 231, which is on the opposite side to the portion where the exhaust tube 231 is connected to the manifold 209, and a pressure sensor 245 as a pressure detector and a pressure adjuster 242 are disposed part way along the exhaust tube 231. The evacuation device 246, the pressure sensor 245, and the pressure adjuster 242 are configured to evacuate the processing chamber 201 so that the pressure therein becomes a predetermined value (a predetermined degree of vacuum). The pressure adjuster 242 and the pressure sensor 245 are electrically connected to a pressure control unit 236, which controls the pressure adjuster 242 at a desired timing to change the pressure in the processing chamber 201 to a desired value based on the pressure detected by the pressure sensor 245.

The seal cap 219 as a furnace opening lid is provided at the lower portion of the manifold 209, the seal cap 219 capable of hermitically blocking the lower end opening of the manifold 209. The seal cap 219 abuts the lower end of the manifold 209 from below in the vertical direction. The seal cap 219 is made of metal, such as stainless steel, and has a disc shape. An o ring 220b is provided on the upper side of the seal cap 219 and serves as a sealing member that abuts the lower end of the manifold 209. A rotation mechanism 254 that rotates the boat is disposed on the opposite side of the seal cap 219 to the processing chamber 201. A rotating shaft 255 of the rotation mechanism 254 passes through the seal cap 219 and is connected to the boat 217, which will be described later. The rotating shaft 255 rotates the wafers 200 by rotating the boat 217. The seal cap 219 is vertically lifted and lowered by a boat elevator 115 as a lifting/lowering mechanism vertically disposed outside the process tube 203, so that the boat 217 can be loaded into and unloaded from the processing chamber 201. The rotation mechanism 254 and the boat elevator 115 are electrically connected to a drive control unit 237, which is configured to control the rotation mechanism 254 and the boat elevator 115 at a desired timing to move in a desired manner.

The boat 217 as a support portion is made of a heat-resistant material, such as quartz, and configured to hold a plurality of wafers 200 with the centers thereof aligned and horizontally placed at multiple levels. A plurality of disc-shaped thermally insulating plates 216 as thermally insulating members made of a heat-resistance material, such as quartz and silicon carbide, are disposed horizontally at multiple levels in the lower portion of the boat 217, so that the heat from the heater 206 is unlikely transferred to the manifold 209.

A temperature sensor 263 as a temperature detector is disposed in the process tube 203. A temperature control unit 238 is electrically connected to the heater 206 and the temperature sensor 263. Adjusting the amount of current flowing into the heater 206 at a desired timing based on the temperature information detected by the temperature sensor 263 allows the temperature distribution in the processing chamber 201 to be a desired one.

The gas flow control unit 235, the pressure control unit 236, the drive control unit 237, and the temperature control unit 238 also form an operation unit and an input/output unit, and are electrically connected to a master control unit 239 that controls the entire substrate processing apparatus. The gas flow control unit 235, the pressure control unit 236, the drive control unit 237, the temperature control unit 238, and the master control unit 239 form a controller 240.

A description will be made of how to use the thus configured processing furnace 202 in conjunction with CVD to form a thin film on the wafers 200 as a step of semiconductor device manufacturing steps. In the following description, the operation of each of the portions that form the substrate processing apparatus is controlled by the controller 240.

When a plurality of wafers 200 are charged into the boat (wafer charging), the boat 217 holding the plurality of wafers 200 is lifted by the boat elevator 115 and loaded into the processing chamber 201 (boat loading), as shown in FIG. 1. In this state, the seal cap 219 seals the lower end of the manifold 209 with the O ring 220b therebetween.

The evacuation device 246 evacuates the processing chamber 201 so that the pressure therein becomes a desired value (a desired degree of vacuum). In this process, the pressure in the processing chamber 201 is measured with the pressure sensor 245, and the pressure adjuster 242 is feedback-controlled based on the measured pressure. The heater 206 heats the processing chamber 201 so that the temperature therein becomes a desired value. In this process, the amount of current flowing into the heater 206 is feedback-controlled based on the temperature information detected by the temperature sensor 263 so that the temperature distribution in the processing chamber 201 becomes a desired one. The rotation mechanism 254 then rotates the boat 217 and hence the wafers 200.

The gas supplied from the process gas supply source and controlled by the MFC 241 so as to flow at a desired flow rate passes through the gas supply tube 232 and enters the processing chamber 201 through the nozzle 230. The introduced gas ascends through the processing chamber 201, flows into the tubular space 250 through the upper end opening of the inner tube 204, and flows out through the exhaust tube 231. The gas, when passing through the processing chamber 201, comes into contact with the surfaces of the wafers 200, and a thin film is deposited on the surface of each of the wafers 200 in a thermal CVD reaction.

After a preset processing time has elapsed, an inert gas is supplied from the inert gas supply source. The inert gas replaces the process gas in the processing chamber 201, and the pressure in the processing chamber 201 returns back to the normal pressure.

The boat elevator 115 then lowers the seal cap 219, so that the lower end of the manifold 209 is opened. At the same time, the processed wafers 200 held in the boat 217 are unloaded (boat unloading) out of the process tube 203 through the lower end of the manifold 209. The processed wafers are then discharged from the boat 217 (wafer discharging).

As an example, the processing conditions for processing the wafers 200 in the processing furnace 202 of the embodiment when a silicon nitride (Si₃N₄) film is formed, for example, are as follows: the processing temperature being 650 to 800° C., the processing pressure being 10 to 500 Pa, the film forming gas species being a silane-based gas (dichlorosilane (SiH₂Cl₂), for example) and ammonia (NH₃), and the film forming gas supply flow rate being 100 to 500 scam for SiH₂Cl₂ and 500 to 5000 scam for NH₃. The wafers 200 are processed by maintaining the processing conditions at fixed values within the respective ranges. Dichlorosilane (SiH₂Cl₂ (abbreviated to DCS)) may be replaced with other silane-based gases, such as trichlorosilane (SiHCl₃ (abbreviated to TCS)) and hexachlorodisilane (Si₂Cl₆ (abbreviated to HCD)).

The inner tube 204 described above will now be described in detail.

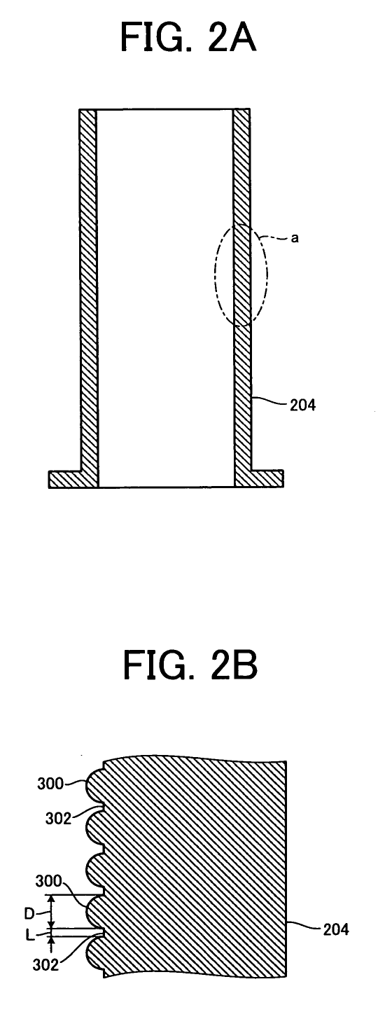

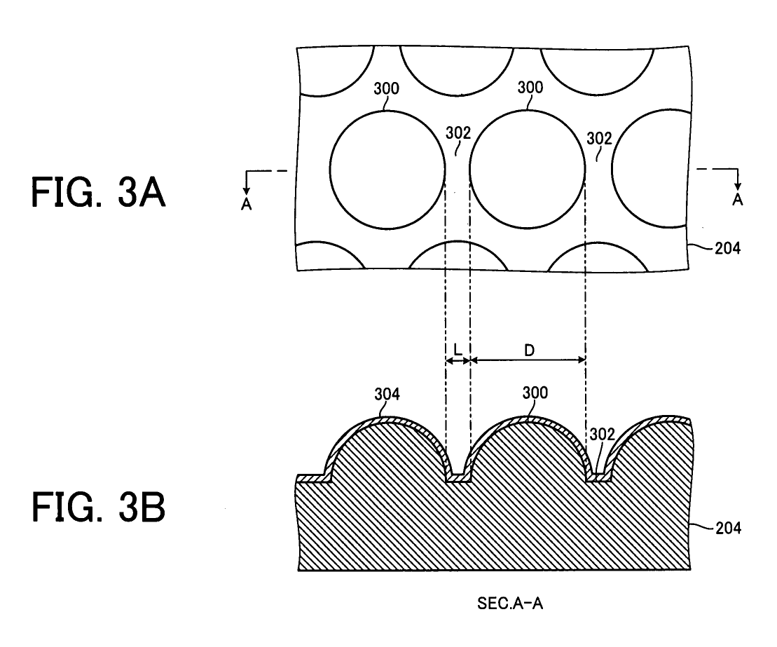

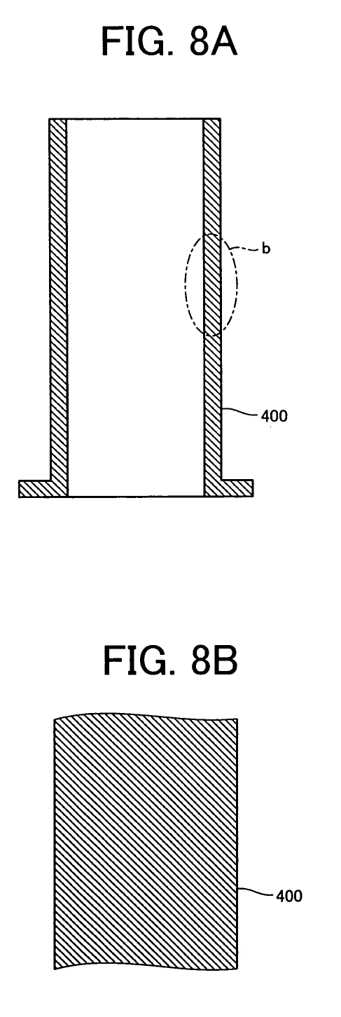

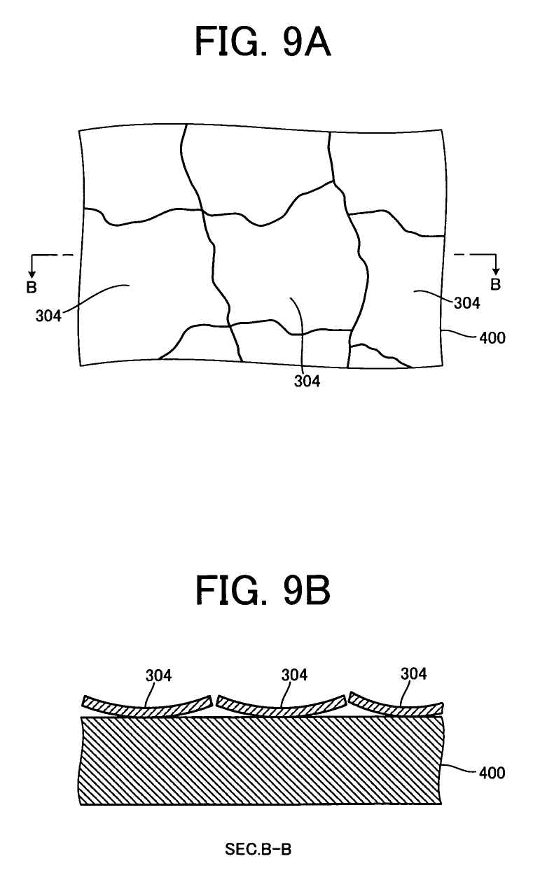

FIGS. 2A, 2B and 3A, 3B show the inner tube 204 in the embodiment, and FIGS. 8A, 8B and 9A, 9B show an inner tube 400 in a comparative example.

FIG. 2A shows the entire inner tube 204 in the embodiment, and FIG. 2B is an enlarged view of the area “a” shown in FIG. 2A. As shown in FIG. 2B, a plurality of projections 300 are provided on the inner wall of the inner tube 204. Each of the projections 300 has a substantially hemispherical shape, and the diameter of the projection 300 (reference character D in FIG. 2B) is larger than 2 μm but smaller than 86 μm. The diameter of the projection 300 is preferably larger than 2 μm but smaller than 86 μm, more preferably larger than 20 μm but smaller than 42 μm. A bottom 302 is formed in the gap between adjacent projections 300. The gap between adjacent projections 300 (reference character L in FIG. 2B) is smaller than 100 μm, preferably smaller than 50 μm. The gap between adjacent projections 300 may not be present (the bottom 302 may not be formed).

On the other hand, FIG. 8A shows the entire inner tube 400 in the comparative example, and FIG. 8B is an enlarged view of the area “b” shown in FIG. 8A. As shown in FIGS. 8A and 8B, the inner wall of the inner tube 400 in the comparative example is not undulated but flat.

FIGS. 3A and 3B show the state of the surface of the inner tube 204 observed under a microscope (a conceptual diagram of a micrograph) in the embodiment in which an SiN (silicon nitride) film 304 is deposited using CVD to a thickness of approximately 1 μm. FIGS. 9A and 9B show the state of the surface of the inner tube 400 observed under a microscope (a conceptual diagram of a micrograph) in the comparative example in which an SiN (silicon nitride) film 304 is deposited using CVD to a thickness of approximately 1 μm.

As shown in FIGS. 9A and 9B, in the comparative example, peeling of the SiN film 304 from the surface of the inner tube 400 periodically occurred at a period of approximately 100 μm. On the other hand, as shown in FIGS. 3A and 3B, on the surface of the inner tube 204 in the invention, no cracking or peeling of the SiN film occurred even when the thickness of the SiN film 304 is the same as that in the comparative example. Forming a plurality of projections 300 on the inner wall of the inner tube 204 thus successively prevented peeling and cracking of the SiN film 304.

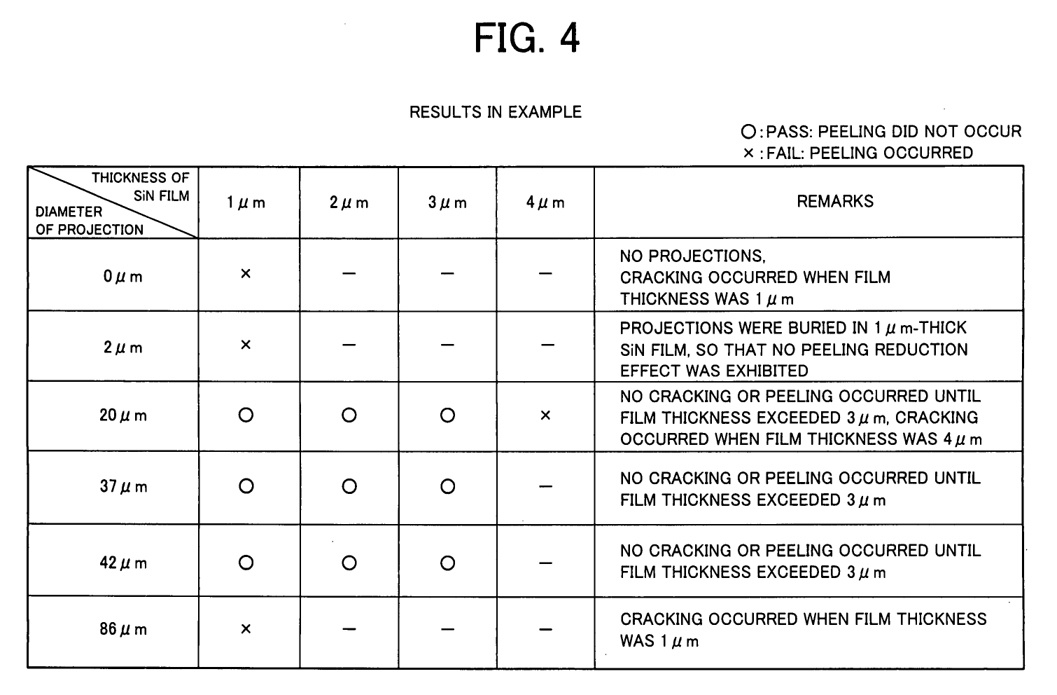

An example will be described with reference to FIG. 4.

### EXAMPLE

The substrate processing apparatus 100 of the above embodiment was used to conduct experiments in which Si₃N₄ films were repeatedly formed under the respective film forming conditions shown in the above embodiment and whether or not cracking and peeling of the deposited film occur was ascertained. The experiments were conducted by changing the diameter of the projections formed on the surface of the inner tube to be 0 μm (no projections), 2 μm, 20 μm, 37 μm, 42 μm, and 86 μm.

FIG. 4 shows the results of the experiments in the example. As shown in FIG. 4, when the diameter of the projections was 0 μm (no projections), cracking occurred in a 1 μm-thick deposited film. When the diameter of the projections was 2 μm, cracking also occurred in a 1 μm-thick deposited film. When the diameter of the projections was 20 μm, cracking occurred in a 4 μm-thick deposited film. When the diameter of the projections was 37 μm, no cracking occurred in the deposited film with a thickness up to 3 μm. When the diameter of the projections was 42 μm as well, no cracking occurred in the deposited film with a thickness up to 3 μm. When the diameter of the projections was 86 μm, cracking occurred in a 1 μm-thick deposited film.

In the inner tubes used in the experiments, some of the adjacent projections were separated (bottoms were formed). The largest size of the gap between such adjacent projections was approximately 50 μm.

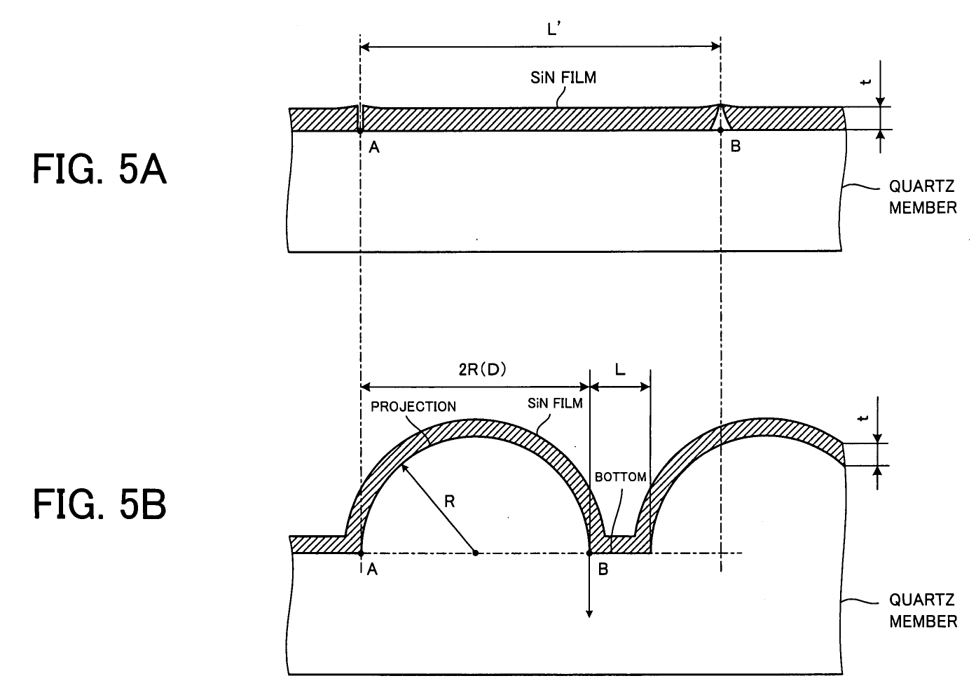

A mechanism explaining how cracking is inhibited in an SiN film deposited on a quartz member on which a plurality of projections having a predetermined size are provided will be described with reference to FIGS. 5A and 5B.

FIG. 5A shows a model in which an SiN film is deposited on the surface of a flat quartz member. FIG. 5B shows a model in which an SiN film is deposited on the surface of a quartz member with a plurality of hemispherical projections (diameter: D, radius: R) provided thereon.

In FIG. 5A, assume that cracking is initiated at a position away from a reference point A (fixed point) by a length L′. The largest stress energy W1 per length L′ in the SiN film can be expressed (approximated) by the following equation (1).

W1=t×σ×σ/E/2×L′=γ×L′ (1)

In the equation, t represents the thickness of the SiN film; E represents Young's modulus of the SiN film; σ represents the stress acting in the SiN film due to the difference in expansion between SiN and quartz; and γ represents the interface energy between quartz and SiN (the deposited film).

On the other hand, in FIG. 5B, when the point A at an end of the hemisphere (projection) is taken as a reference, the position on the hemisphere where the largest stress acts in the SiN film is the point B, and the stress acts downward (the direction of the arrow C in FIG. 5B). The stress does not act on the area beyond the point B, that is, the area on the right of the point B. Therefore, the largest stress energy W2 in the SiN film in this system can be expressed by the following equation (2).

W2=t×σ×σ/E/2×π×R=γ×πR (2)

Therefore, no cracking occurs in the SiN film in FIG. 5B when the conditional expression W1>W2 is satisfied. Substituting the equations (1) and (2) into W1>W2 derives the following equation (3).

2R<L′/(π/2) (3)

For example, when L′ is 100 μm (corresponding to the comparative example in FIGS. 9A and 9B), 2R(=D)<64 μm is derived from the above equation (3).

When adjacent projections are not separated, the SiN film deposited on each of the projections can be considered as an independent film. When the diameter (D) of the projections satisfies D<64 μm, the film thickness at which cracking is initiated in the SiN film can be greater than 1 μm in consideration of the comparative example in FIGS. 9A and 9B.

On the other hand, as shown in FIG. 5B, when adjacent projections are separated, the SiN film deposited on each of the projections and the film deposited in the gap (bottom) between adjacent projections can be considered as independent films.

First, consider the SiN film deposited on each of the projections. The SiN film deposited on each of the projections can be handled in a manner similar to the case described above where adjacent projections are not separated. When the diameter (D) of the projections satisfies D<64 μm, the film thickness at which cracking is initiated in the SiN film can be greater than 1 μm. Next, consider the SiN film deposited on the bottom. Let L (μm) be the size of the gap between adjacent projections, and t (μm) be the thickness of the SiN film. In consideration of the fact in the comparative example in FIGS. 9A and 9B that cracking periodically occurs in the SiN film at a period of 100 μm when the film thickness reaches 1 μm, cracking will occur in the SiN film when the conditional expression L×t=100 μm×1 μm is satisfied. For example, when L is 100 μm, cracking is initiated in the SiN film when t is 1 μm. In another example, when L is 50 μm, cracking is initiated in the SiN film when t is 2 μm. In another example, when L is 30 μm, cracking is initiated in the SiN film when t is 3.3 μm. That is, for example, when L is smaller than 100 μm, the film thickness at which cracking is initiated in the SiN film can be greater than 1 μm. In another example, when L is smaller than 50 μm, the film thickness at which cracking is initiated in the SiN film can be greater than 2 μm. In another example, when L is smaller than 30 μm, the film thickness at which cracking is initiated in the SiN film can be greater than 3.3 μm. That is, it is seen that the film thickness at which cracking is initiated in the SiN film can be greater than t μm by setting L to a value smaller than 100 μm/t.

The results of the experiments in the above example (shown in FIG. 4) have ascertained that when the diameter D of the projections is 2 μm or smaller (D<2 μm), cracking is initiated in a 1 μm-thick SiN film. This result is attributable to the fact that no peeling reduction effect is provided when the diameter of the projections is too small, because the projections are buried in a 1 μm-thick SiN film. Therefore, the diameter D of the projections needs to be greater than 2 μm (D>2 μm) so that the projections will not be buried in a 1 μm-thick SiN film.

On the other hand, when the diameter D of the projections is 86 μm or greater (D>86 μm), it has been ascertained that cracking is initiated in a 1 μm-thick SiN film. That is, it is seen that when the diameter of the projections is too large, no peeling reduction effect is provided as well. Therefore, the diameter D of the projections needs to be smaller than 86 μm (D<86 μm).

When the diameter D of the projections is any of 20 μm, 37 μm, and 42 μm (20 μm≦D≦42 μm), it has been ascertained that no cracking occurs in the SiN film having a thickness of 1 μm, 2 μm, and 3 μm. When the diameter of the projections is 20 μm, it has been ascertained that cracking is initiated in a 4 μm-thick SiN film. Theoretically, when the diameter D of the projections is set to a value smaller than 64 μm (D<64 μm), the film thickness at which cracking is initiated in the SiN film can be greater than 1 μm.

When a gap is present between adjacent projections, it had been thought that the film thickness at which cracking or peeling is initiated in the SiN film deposited in the gap can be theoretically greater than or equal to 3 μm only when the length of the gap between adjacent projections is 33 μm or smaller. The results of the experiments in the above example, however, have ascertained that the film thickness at which cracking or peeling is initiated can be greater than or equal to 3 μm even when the length of the gap between adjacent projections is 50 μm or smaller.

It is seen from the above discussion that the diameter D of the projections needs to be greater than 2 μm but smaller than 86 μm (2 μm<D<86 μm) in order to prevent cracking from occurring in a 1 μm-thick SiN film. Theoretically, the diameter D of the projections is preferably smaller than 64 μm (D<64 μm). More preferably, the diameter of the projections is greater than or equal 20 μm but smaller than or equal to 42 μm (20 μm<D<42 μm). In this way, no cracking will occur in the SiN film even when the film thickness reaches 3 μm.

As described above, according to the invention, when a plurality of projections are provided on the inner wall of the reaction tube and the diameter of the projections are set to the predetermined size described above, the film thickness at which cracking or peeling is initiated in the SiN film can be, for example, 3 μm or greater, and the frequency of removing and cleaning the SiN film can be reduced by a factor of three or greater. The operating rate of the apparatus can thus be improved.

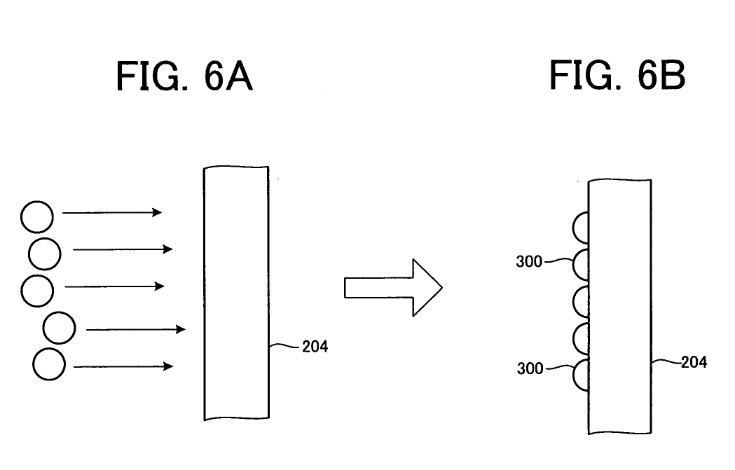

As shown in FIGS. 6A and 6B, the projections 300 on the surface of the inner tube 204 can be formed, for example, by known flame spraying. When flame spraying is used to form the projections, quartz particles to be sprayed onto the surface of the quartz member (inner tube 204) have a substantially spherical shape. After sprayed, most of the quartz particles become substantially hemispherical, whereas some of them are squashed. A plurality of projections 300 may be provided on the surface of the boat 217 and the inner wall of the outer tube 205 as well as the inner tube 204.

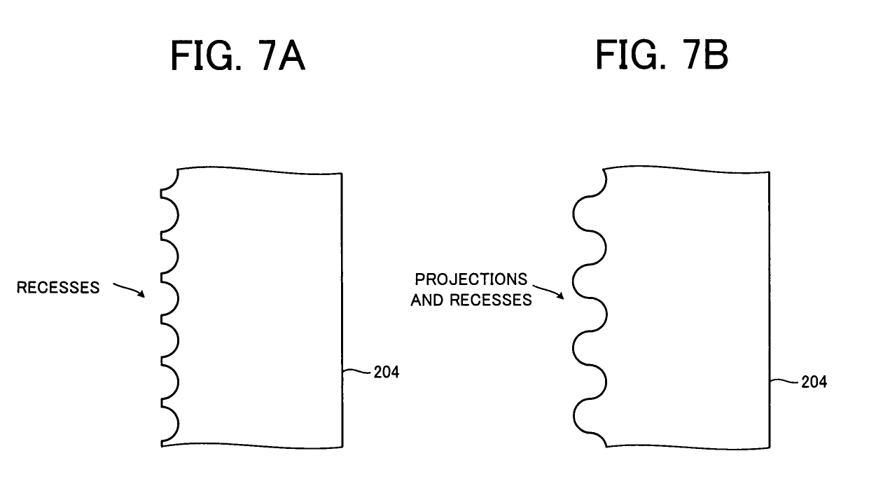

In the embodiment, although the description has been made with reference to the case where a plurality of projections are provided on the surface of a quartz member, the resultant structure may not necessarily have projections. For example, the structure may have recesses shown in FIG. 7A, or may have projections and recesses shown in FIG. 7B.

In related art, when an SiN film is formed, peeling is initiated when the thickness of the deposited film attached to the surface of a quartz member becomes approximately 1 μm. Therefore, it is necessary to perform cleaning whenever a film approximately 1 μm thick is formed. On the other hand, when a poly-Si film is formed, for example, no peeling occurs even when the thickness of the deposit film attached to the surface of a quartz member becomes 10 μm, so that the cleaning is carried out less frequently. That is, the problem in the invention is frequently found particularly in SiN film formation, and it can therefore be said that the invention provides an effective technology particularly in SiN film formation.

While the description has been made in the embodiment with reference to the case where CVD is used as the film formation method, the film formation method is not limited thereto. For example, an ALD (Atomic Layer Deposition) may be used.

The invention is applicable to a substrate processing apparatus that processes a substrate, such as a semiconductor wafer and a glass substrate, and a method for manufacturing a semiconductor device, particularly to those in which the operating rate of the apparatus needs to be improved.

What is claimed is:

1. A substrate processing apparatus comprising:
a reaction tube that processes a substrate;
a support portion that supports the substrate in the reaction tube;
a process gas supply line that supplies a process gas into the reaction tube; and
an exhaust line that exhausts an inside of the reaction tube,
wherein the process gas is supplied into the reaction tube to form a silicon nitride film on the substrate,
at least the reaction tube is made of quartz,
a plurality of projections are provided on the inner wall of the reaction tube, and
the diameter of the projections is larger than 2 μm but smaller than 86 μm.

2. The substrate processing apparatus according to claim 1, wherein the diameter of the projections is larger than 2 μm but smaller than 64 μm.

3. The substrate processing apparatus according to claim 1, wherein the diameter of the projections is larger than or equal to 20 μm but smaller than or equal to 42 μm.

4. The substrate processing apparatus according to claim 1, wherein the length of the gap between adjacent pairs of the projections is smaller than 100 μm.

5. The substrate processing apparatus according to claim 1, wherein the length of the gap between adjacent pairs of the projections is smaller than or equal to 50 μm.

6. The substrate processing apparatus according to claim 1, wherein the support portion is made of quartz,
a plurality of projections are provided on the surface of the support portion, and
the diameter of the projections is larger than 2 μm but smaller than 86 μm.

7. The substrate processing apparatus according to claim 1, wherein the reaction tube includes an inner tube and an outer tube provided outside the inner tube,
a plurality of projections are provided on the inner walls of the inner and outer tubes, and
the diameter of the projections is larger than 2 μm but smaller than 86 μm.

8. A substrate processing apparatus comprising:
a reaction tube that processes a substrate;
a support portion that supports the substrate in the reaction tube;
a process gas supply line that supplies a process gas into the reaction tube; and
an exhaust line that exhausts an inside of the reaction tube,
wherein the process gas is supplied into the reaction tube to form a silicon nitride film on the substrate,
at least the reaction tube is made of quartz,
a plurality of projections are provided on the inner wall of the reaction tube, and
the length of the gap between adjacent pairs of the projections is smaller than 100 μm.

9. A substrate processing apparatus comprising:
a reaction tube that processes a substrate;
a support portion that supports the substrate in the reaction tube;
a silane-based gas supply line that supplies a silane-based gas into the reaction tube;
an ammonia gas supply line that supplies ammonia gas into the reaction tube; and
an exhaust line that exhausts an inside of the reaction tube,
wherein the silane-based gas and ammonia gas are supplied into the reaction tube to form a silicon nitride film on the substrate,
at least the reaction tube is made of quartz,
a plurality of projections are provided on the inner wall of the reaction tube,
the diameter of the projections is larger than or equal to 20 μm but smaller than or equal to 42 μtm, and
the length of the gap between adjacent pairs of the projections is smaller than or equal to 50 μm.

10. A method for manufacturing a semiconductor device, comprising the steps of:
loading a substrate into a reaction tube made of quartz with a plurality of projections provided on the inner wall of the reaction tube, the diameter of the projections being larger than 2 μm but smaller than 86 μm,
supplying a process gas into the reaction tube to form a silicon nitride film on the substrate; and
unloading the substrate on which the silicon nitride film has been formed from the reaction tube.

11. A method for manufacturing a semiconductor device, comprising the steps of:
loading a substrate into a reaction tube made of quartz with a plurality of projections provided on the inner wall of the reaction tube,
supplying a process gas into the reaction tube to form a silicon nitride film on the substrate; and
unloading the substrate on which the silicon nitride film has been formed from the reaction tube,
wherein when the film thickness at which cracking or peeling is initiated in the silicon nitride film deposited on the inner wall of the reaction tube is set to a value larger than t μm, the length of the gap between adjacent pairs of the projections is set to a value smaller than 100 μm/t.
